(19) United States
(12) Patent Application Publication
(10) Pub. No.: US 2022/0341053 A1
(43) Pub. Date: Oct. 27, 2022

(54) PLATING MACHINE WITH TREATMENT UNITS ARRANGED ON CIRCUMFERENCE

(71) Applicant: NATIONAL INSTITUTE OF ADVANCED INDUSTRIAL SCIENCE AND TECHNOLOGY, Tokyo (JP)

(72) Inventors: Shiro HARA, Ibaraki (JP); Fumito IMURA, Ibaraki (JP); Sommawan KHUMPUANG, Ibaraki (JP); Yuuki ISHIDA, Tokyo (JP); Toshihiro KIKUNO, Kumamoto (JP); Takafumi YOSHINAGA, Kumamoto (JP); Kayo KAMASAKI, Kumamoto (JP); Mitsuhiko FUKUYAMA, Fukuoka (JP); Tetuya MORIZONO, Kumamoto (JP)

(73) Assignee: NATIONAL INSTITUTE OF ADVANCED INDUSTRIAL SCIENCE AND TECHNOLOGY, Tokyo (JP)

(21) Appl. No.: 17/718,756

(22) Filed: Apr. 12, 2022

(30) Foreign Application Priority Data
Apr. 22, 2021 (JP) 2021-072823

(51) Int. Cl. C25D 17/08; C25D 17/00

(52) U.S. Cl. CPC C25D 17/08; C25D 17/001

(57) ABSTRACT

The plating machine 1 comprises a plurality of treatment units 14 and a conveying means 13 that conveys a wafer W to the plurality of treatment units 14, wherein the conveying means 13 includes an arm 31 that is provided, on one end side, with a plating tool 32 that holds the wafer W, and an arm rotation drive unit 33 that rotates the arm 31 around another end side of the arm 31, and the plurality of treatment units 14 is arranged at predetermined intervals on a rotation trajectory of the plating tool 32.

### TECHNICAL FIELD

The present invention relates to a plating machine used for plating a wafer with Cu and the like.

### BACKGROUND ART

Recently, as a production line for semiconductor devices which uses such a plating machine, a layout based on. a job shop system has been mainly employed. In the job shop system, a plurality of units, which is referred to as bays in which the semiconductor processing machines having the same kind of functions are collectively arranged, is provided within a large clean room, and the bays are connected to each other via a robot for conveyance or a belt conveyor. As a work to be processed in the production line described above, a large diameter wafer having the diameter of, for example, 12 inches is used, and thousands of semiconductor chips are obtained from a single wafer.

However, in this job shop system, in the case where a plurality of similar processes is repeated, conveyance distances inside a bay and/or among the bays increase, and waiting time increases accordingly. This causes increased production time and/or increased products in progress, which results in an increased cost, and especially in the production line for producing a large number of semiconductor chips, causes a problem of low productivity. In view of this problem, a production line based on a flow shop system in which the semiconductor processing machines are arranged in the order of processes has been proposed instead of the conventional production line based on the job shop system.

The production line based on the flow shop system is suitable for the case of producing a large number of the same products, however, in the case of producing other products, it is necessary to change a production procedure (recipe) and also rearrange the installation location of each. semiconductor processing machines in the production line in accordance with the order of the processing flow of the semiconductor chips to be produced. However, in view of efforts and time, rearrangement of the semiconductor processing machines at every change of the semiconductor chips to be processed is not practical. Especially, considering that huge semiconductor processing machines are installed and fixed in a clean room which is a closed space, it is practically impossible to rearrange the semiconductor processing machines in each case.

Furthermore, there is also a demand of production of very low volume of semiconductors whose production unit is from a few to several hundred, which are, for example, engineer samples and ubiquitous sensors. However, producing very low volume of semiconductors in a huge production line based on the on shop system or the flow ship system described above causes a remarkable deterioration of cost efficiency. Accordingly, in this case, different semiconductors need to be produced in the same production line.

However, producing different semiconductors at the same time causes a reduction in productivity of the production Line which becomes worse with an increase in the number of varieties of the semiconductors to be produced. Thus, the huge production line is not suitable for very low-volume and high-mix production.

In a plating machine used in this type of production line, a guide rail is arranged in a substantially eliptical shape, and treatment units for plating a plate-shaped object such as a printed circuit board, which are, for example, a pre-treatment tank, a plating tank., and a water washing tank, are arranged side by side along the guide rail. This plating machine is designed to move the plate-shaped object along the guide rail so that the plate-shaped object can be sequentially conveyed to the pre-treatment tank, the plating tank, the water washing tank, and the like, whereby the processes by the pre-treatment tank, the plating tank, the water washing tank, and the like are sequentially performed (for example, see Patent Literature 1).

### CITATIONLIST

### Patent Literature

Patent Literature 1: JP-A-2002-363796

### SUMMARY OF INVENTION

### Technical Problem

In the above-described prior art disclosed in Patent Literature 1, the plate-shaped object is moved along the guide rail so as to be sequentially conveyed to the pre-treatment tank, the plating tank, the water washing tank, and the like, whereby the processes of plating the plate-shaped object are continuously performed. In order to sequentially convey the plate-shaped object to the pre-treatment tank, the plating tank, the water washing tank, and the like, these tanks are required to be arranged side by side along the guide rail, which makes the structure necessary for conveying the plate-shaped object complex.

The present invention has been made in view of the above-described actual circumstances of the prior art, and an object thereof is to provide a plating machine capable of conveying a wafer with a simple structure.

### Solution to Problem

In order to achieve the object above, the present invention provides a plating machine comprising: a plurality of treatment units; and a conveying means that conveys a wafer to the plurality of treatment units, the conveying means including an arm that is provided, on one end side, with a holding unit that holds the wafer, and an arm rotation drive unit that rotates the arm around another end side of the arm, and the plurality of treatment units being arranged at predetermined intervals on a rotation trajectory of the holding unit.

According to the present invention having the structure described above, the plurality of treatment units is arranged at predetermined intervals on the rotation trajectory of the holding-unit which can be obtained by the rotation of the arm, and accordingly, through a simple operation of rotating the arm by the arm rotation drive unit, it is possible to convey the wafer held by the holding unit to the plurality of treatment units.

In order to achieve the object above, in the present invention, the conveying means includes a vertical movement drive unit that moves the holding unit upward and downward.

According to the present invention having the structure described above, the vertical movement drive unit moves the holding unit upward and downward, and accordingly, it is possible to carry the wafer held by the holding unit in and out from the plurality of treatment units.

In order to achieve the object above, in the present invention, the holding unit is rotatably supported around an axis thereof by the arm, and the conveying means includes a wafer rotation drive unit that rotates the holding unit around the axis thereof.

According to the present invention having the structure described above, the wafer rotation drive unit rotates the holding unit around the axis thereof so that the wafer held by the holding unit can be rotated around the axis thereof, and accordingly, it is possible to drain, for example, the liquid adhering to the wafer or dry the wafer.

In order to achieve the object above, in the present invention, a stage on which the wafer is delivered is provided, and the stage includes a wafer reversing unit that reverses the wafer delivered on the stage and conveys the wafer which has been reversed to the holding unit of the conveying means.

In order to achieve the object above, in the present invention, the wafer delivered on the stage is reversed by the wafer reversing unit and then conveyed to the holding unit of the conveying means, and accordingly, for example, even when, at the time of being delivered on the stage, a surface to be plated is positioned on the upper side of the wafer, the wafer can be conveyed to each of the treatment units after being turned over. As a result, it is possible to easily plate a wafer even in a tank-shaped treatment unit filled with, for example, the plating solution.

In order to achieve the object above, in the present invention, the wafer has a surface to be treated on one of upper and lower sides, the wafer is delivered on the stage with the surface to be treated facing upward, the wafer reversing unit reverses the wafer delivered on the stage and conveys the wafer to the holding unit with the surface to be treated facing downward, and the plurality of treatment units performs treatment on the surface to be treated of the wafer which has been facing downward.

According to the present invention having the structure described above, the wafer which has been delivered to the stage with the surface to be treated facing upward is turned over by the wafer reversing unit and conveyed to the holding unit of the conveying means with the surface to be treated facing downward, and accordingly, it is possible to prevent damage to the surface to be treated of the wafer until the wafer is conveyed from the stage to the holding unit of the conveying means. Furthermore, the plurality of treatment units performs processes on the surface to be treated of the wafer facing downward, which means that the plurality of treatment units performs the processes only on the surface to be treated on the lower side of the wafer, and accordingly, it is possible to simplify the processes for the wafer performed by the plurality of units.

In order to achieve the object above, in the present invention, the wafer is formed into a disc-shape having an outside diameter of 12.5 mm.

According to the present invention having the structure described above, the wafer is formed into a disc shape having the outside diameter of 12.5 mm, and accordingly, the wafer is the one used in a so-called minimal fab system.

### Advantageous Effects of Invention

According to the present invention, a plurality of treatment units is arranged at predetermined intervals on rotation trajectory of a holding unit, and therefore, it is possible to convey a wafer held by the holding unit to the plurality of treatment units through a simple operation of rotating an arm.

### BRIEF DESCRIPTION OF DRAWINGS

FIG. 1 is a schematic cross-sectional view of a housing in which a plating machine according to an embodiment of the present invention is housed.

FIG. 2 is a perspective view of the housing.

FIG. 3 is a schematic plan view of the plating machine.

FIG. 4A illustrates and explains a stage, a lower part, and a wailer reversing mechanism which are included in the plating machine, when a wafer is delivered.

FIG. 4B illustrates and explains a stage, a lower part, and a wafer reversing mechanism which are included in the plating machine, when the arm is rotated.

FIG. 4C illustrates and explains a stage, a lower part, and a wafer reversing mechanism which are included in the plating machine, when an arm is moved upward.

FIG. 40D illustrates and explains a stage, a lower part, and a wailer reversing mechanism which are included in the plating machine, when the wafer is placed.

FIG. 5 illustrates and explains a holding member and a conveying means included in the plating machine.

FIG. 6 is a side view of the holding member included in the plating machine.

FIG. 7 is a schematic view of an internal structure of the holding member included in the plating machine.

FIG. 8 is a schematic view illustrating a state where the holding member included in the plating machine immersed in a treatment tank.

FIG. 9 is a schematic view of a treatment tank included in the plating machine.

FIG. 10A. illustrates and explains the holding member, the conveying means, and a removal means included in the plating machine, before an upper part is inserted.

FIG. 10B illustrates and explains the holding member, the conveying means, and a removal means included in the plating machine, when the upper part is inserted.

FIG. 10C illustrates and explains the holding member, the conveying means, and a removal means included in the plating machine, when the holding member is moved upward.

FIG. 10D illustrates and explains the holding member, the conveying means, and a removal means included in the plating machine, when the holding member is moved downward.

FIG. 10E illustrates and explains the holding member, the conveying means, and a removal means included in the plating machine, when. the removal means is operated.

FIG. 10F illustrates and explains the holding member, the conveying means, and a removal means included in time plating machine, when the upper part has been removed.

FIG. 11 illustrates and explains a pressure state when air is sucked from a suction port of the plating machine.

FIG. 12 is a schematic cross-sectional view of the housing, which illustrates the pressure state when air is sucked from the suction port of the plating machine.

FIG. 13 illustrates and explains a pressure state when warm air is supplied to a drying unit of the plating machine.

FIG. 14 is a schematic cross-sectional view of the housing, which illustrates the pressure state when warm air is supplied to the drying unit of the plating machine.

### DESCRIPTION OF EMBODIMENTS

Hereinafter, an embodiment of the present invention will be described with reference to the drawings.

### <Overall Structure>

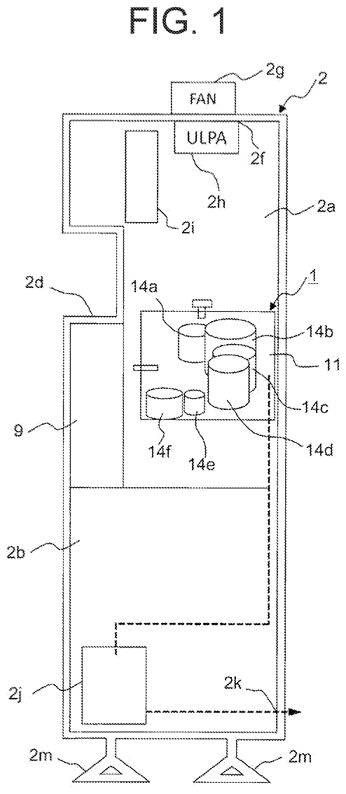

A plating machine 1 according to one embodiment of the present invention is used for plating, with Cu and the like, a surface B to be treated which is a surface of a wafer W. As illustrated in FIG. 1, the plating machine 1 is housed in a housing 2 having a size standardized in advance. The housing 2 is standardized based on the minimal fab concept (minimal fabrication concept). Here, the minimal fab concept is the ideal solution for high-mix and low-volume semiconductor production. The minimal fab concept can respond to various types of resource saving, energy saving, investment saving, and/or high performance fabrication, and can realize a minimal production system for reducing the scale of production which is, for example, disclosed in JP 2012-54414 A.

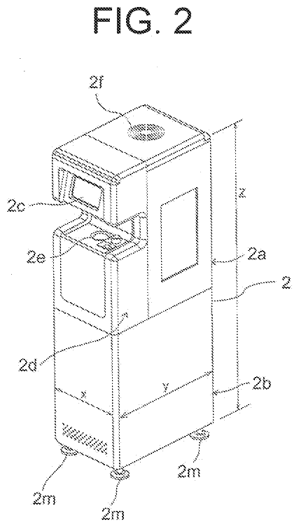

As illustrated. in FIG. 2, the housing 2 has a vertically extending and substantially rectangular parallelepiped shape having a uniform size, which is 0.30 m in width( x)×0.45 m in dept(y)×1.44 m in height(z). The housing 2 is designed to block the entry of fine particles and gas molecules into its inside. The housing 2 consists of a housing upper portion 2a on the upper side and a housing lower portion 2b on the lower side.

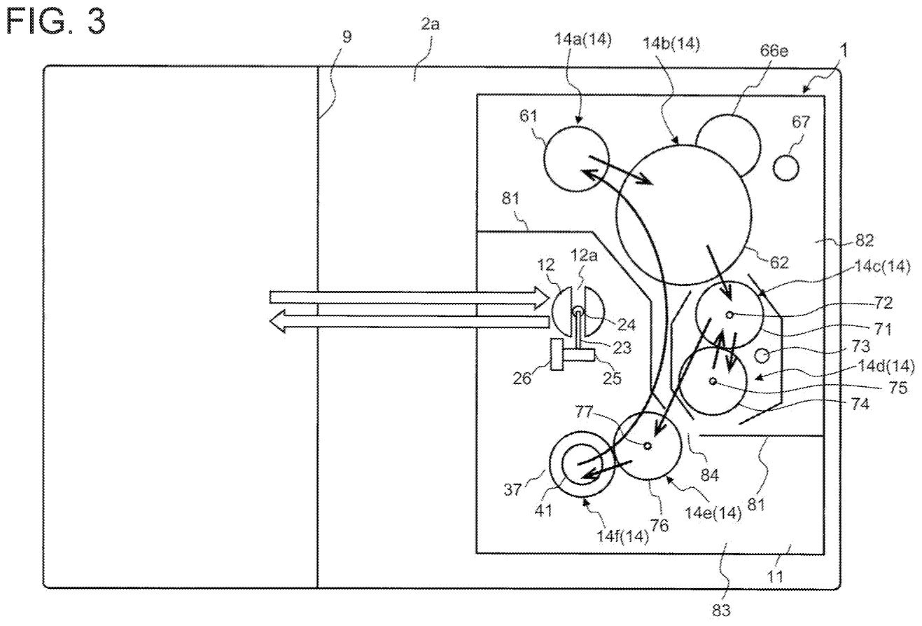

As illustrated in FIG. 1 and FIG. 3, the plating machine 1 is housed in the housing upper portion 2a. As illustrated in FIG. 1 and FIG. 2, an intermediate portion of the housing upper portion 2a in the vertical direction has a recessed shape as seen from the side, which is the shape obtained by providing the front side of the housing upper portion 2a with a recess. On the front side on the upper side of the housing upper portion 2a, an operation panel 2c is mounted. On the lower side of the recessed portion of the housing upper portion 2a, a front chamber 2d through which the wafer W is carried into and out from the housing 2 is provided. On the substantially central portion of the top surface of the front chamber 2d, a substantially circular docking port 2e serving as a shuttle housing unit used to install a shuttle (not illustrated) as a conveying container is provided.

The front chamber 2d is designed to block the entry of fine particles and gas molecules into the housing 2. That is, the front chamber 2d houses a PLAD (Particle Lock Air-tight Docking) system 9 serving as a conveying device which carries the wafer W installed in the shuttle in and out from the housing 2 without letting the wafer W to be exposed to the outside air. The PLAD system 9 is designed to carry the wafer W, which has been conveyed from the docking port 2e with the surface B to be treated facing upward, to a predetermined position of the plating machine 1, and carry out the wafer W after being plated by the plating machine 1 to the docking port 2e.

As illustrated in FIG. 2, an air vent 2f through which the air outside the housing 2, namely, the outside air is taken into the housing 2 is provided on the upper side of the housing upper portion 2a. As illustrated in FIG. 1, a fan 2g serving as an air intake means is mounted on the upper side of the air vent 2f, namely, the top surface of the housing 2. An air filter 2h for capturing particles contained in the air taken in by the fan 2g is mounted on the lower side of the fan 2g. As the air filter 2h, for example, a ULPA filter (Ultra Low Penetration Air Filter) is used. Furthermore, a rectifier 2i for rectifying the air taken. in by the fan 2g is provided in the housing upper portion 2a.

The housing lower portion 2b houses, for example, control device (not illustrated) for controlling the plating machine 1 provided in the housing upper portion 2a, various chemical solution tanks for storing treatment liquids used by the plating machine 1 such as a plating solution M, pure water, and a post-treatment solution, and a drain tank (not illustrated). Furthermore, as illustrated in FIG. 1, the housing lower portion 2b includes a scrubber 2j serving as a suction device for sucking the air containing chemicals, which is a treatment liquid such as the plating solution M, in the form of a harmful mist generated in the plating machine 1 to remove the chemicals therefrom. On the back surface of the housing lower portion 2b, a discharge outlet 2k serving as an outlet for discharging the air, from which the chemicals in the form of a mist have been adsorbed and removed by the scrubber 2j, to the outside of the housing 2. As illustrated in FIG. 2, support members 2m for supporting the housing 2 are provided. on the lower surface of the housing lower portion 2b.

### <Plating Machine>

The wafer W to be plated by the plating machine 1 includes a circular surface having a predetermined size, for example, which is 12.5 mm (half-inch size), and is formed in a disc shape composed of single crystal silicon (Si). A predetermined pattern is formed on a surface of the wafer W, which is the surface B to be treated before being plated. The plating machine 1 plats only the surface B to be treated of the wafer W.

Specifically, as illustrated in FIG. 1 and FIG. 3, the plating machine 1 includes a plating chamber 11 that is installed on the rear side and upper portion of the front chamber 2d in the housing 2. The plating chamber 11 is controlled to be in a negative pressure state by the fan 2g as compared with the other portions in the housing 2. The plating chamber 11 includes a stage 12 that is a reception table serving as a reception unit on which the wafer W is delivered from the PLAD system 9, a conveying means 13 for conveying the wafer W which has been delivered on the stage 12, and a plurality of treatment units 14 each of which is a treatment unit for plating the wafer W which has been delivered on the stage 12.

As illustrated in FIG. 3, the plurality of treatment units 14 is arranged side by side on the same circumference around the center position of the stage 12. Furthermore, the plurality of treatment units 14 is installed side by side to each other on the circumference, from the upper side to the lower side in FIG. 3 in the order of a pre-treatment unit 14a, a plating unit 14b, a water washing unit 14c, a post-treatment unit 14d, a drying unit 14e, and a wafer housing unit 14f. These pre-treatment unit 14a, the plating unit 14b, the water washing unit 14c, the post-treatment unit 14d, the drying unit 14e, and the wafer housing unit 14f are arranged such that the center positions thereof are arranged side by side on the same circumference around the center position of the stage 12, respectively.

As illustrated in FIG. 3, the stage 12 includes an insertion recess 12a that divides the stage 12 into two parts. The insertion recess 12a penetrates the stage 12 both vertically and the horizontally. Furthermore, the stage 12 includes a wafer reversing mechanism 22 serving as a wafer reversing unit for revering the front and back surfaces of the wafer W installed on the stage 12. The wafer reversing mechanism 22 includes a reversing arm 23, a suction pad 24 attached to the distal end side of the reversing arm 23, a rotation drive unit 25 attached to the proximal end side of the reversing arm 23, and a vertical movement drive unit 26 for moving the reversing arm 23 upward and downward in the vertical direction.

The reversing arm 23 of the wafer reversing mechanism 22 is mounted, in a state of waiting for the wafer W to be delivered on the stage 12, such that the distal end side thereof is inserted into the insertion recess 12a of the stage 12. The reversing arm 23 can be rotated around the proximal end side thereof by the rotation drive unit 25, and furthermore, can be moved upward and downward in the vertical direction by the vertical movement drive unit 26.

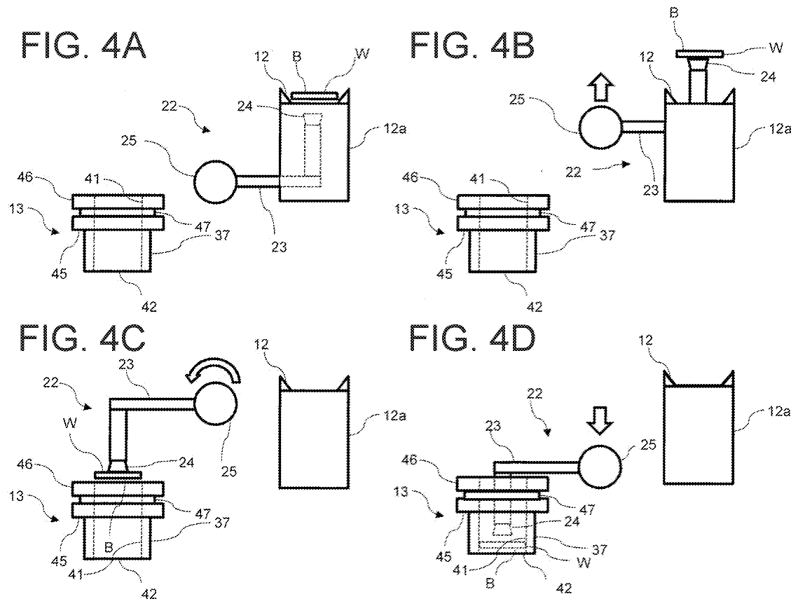

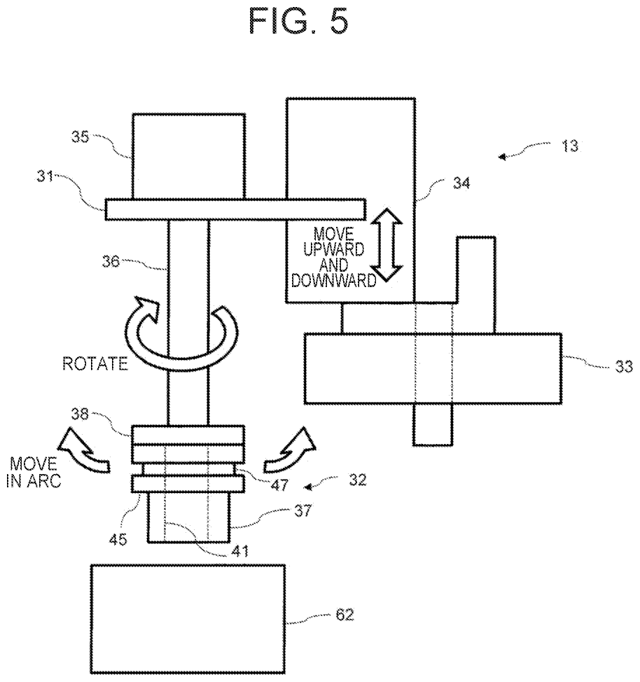

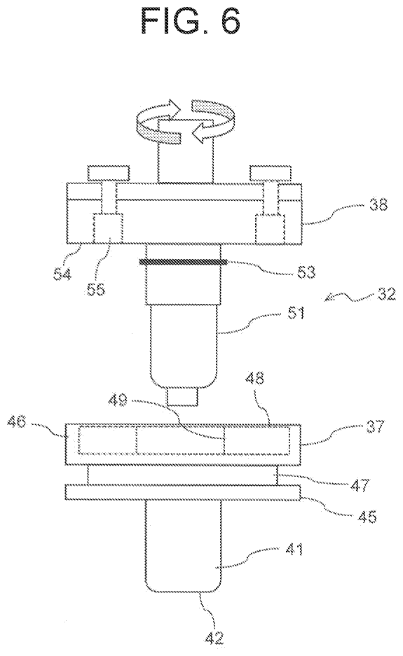

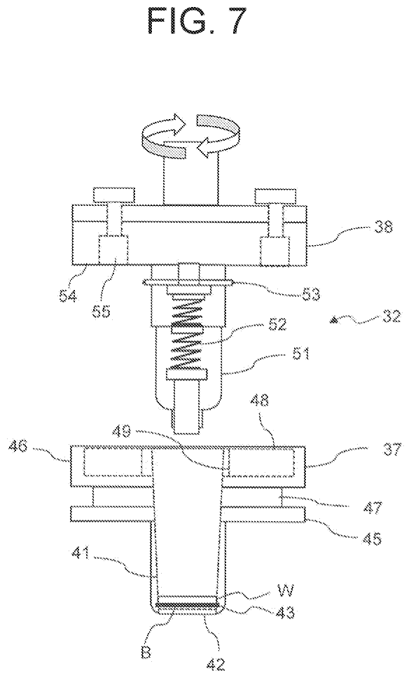

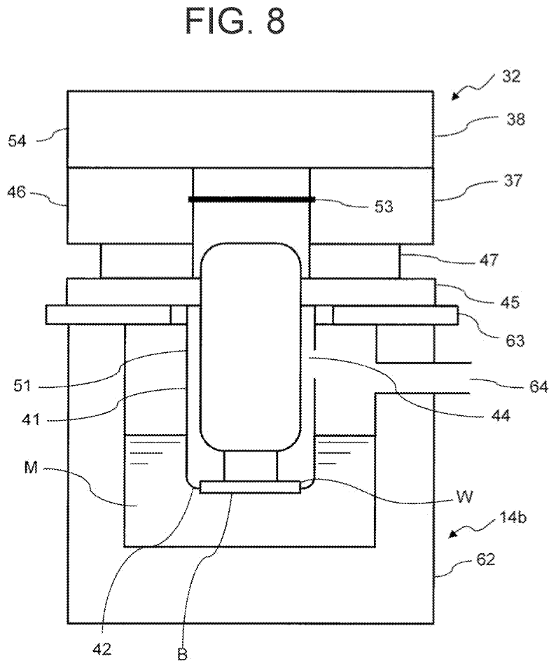

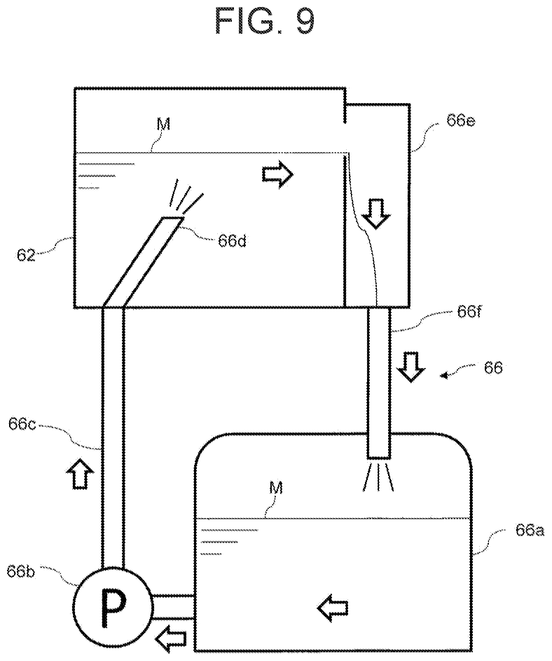

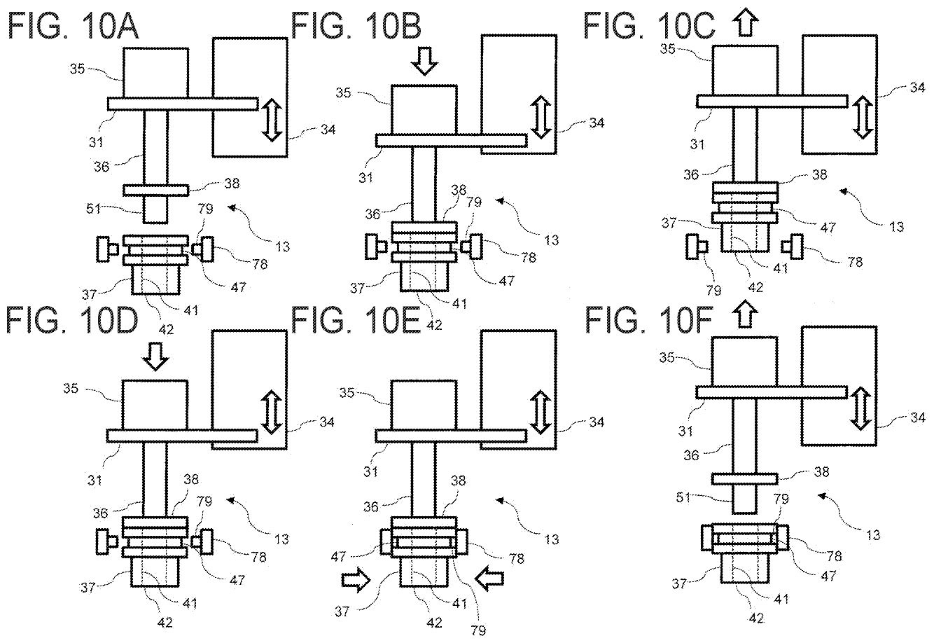

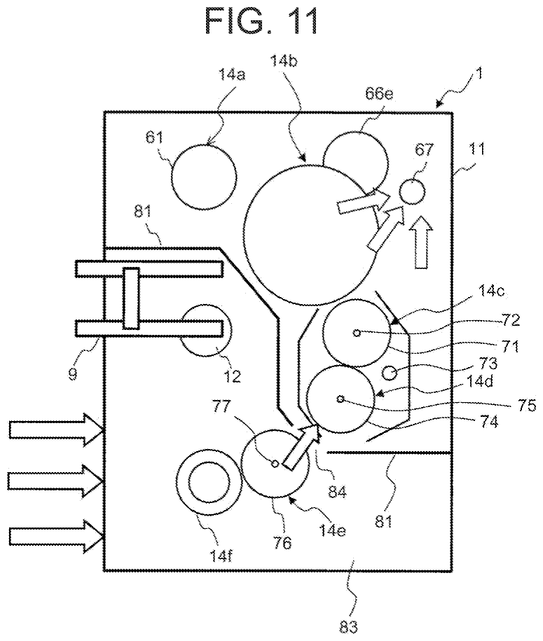

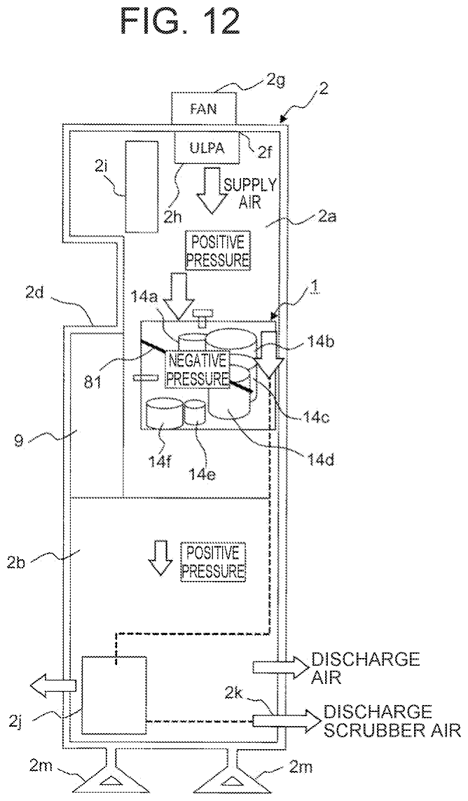

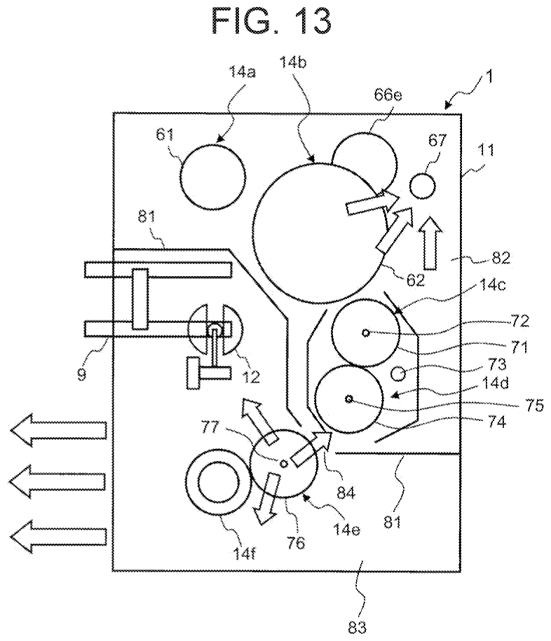

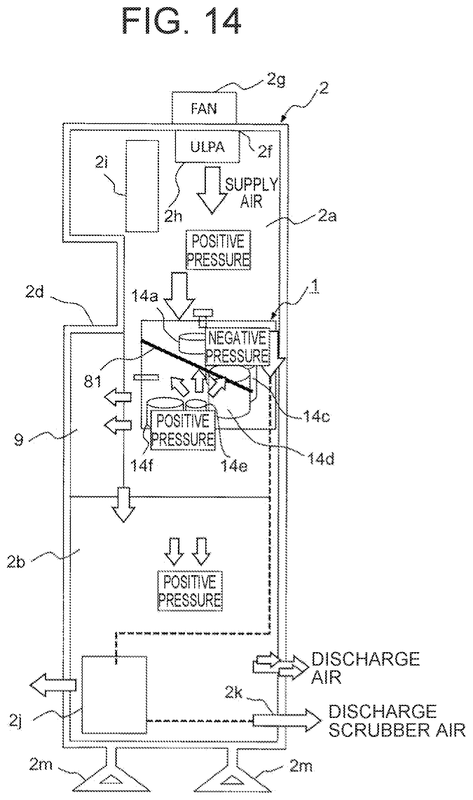

The suction pad 24 is a so-called vacuum chuck, and is mounted to the distal end portion of a support piece 23a which is mounted. at the right angle to the distal end side of the reversing arm 23. Furthermore, as illustrated in FIG. 4A, the distal end side of the reversing arm 23 is inserted into the insertion recess 12a of the stage 12, and the suction pad 24 is mounted so as to face upward in a state where the longitudinal direction of the reversing arm 23 is directed toward the horizontal direction. Thus, the suction pad 24 detachably sucks the back surface of the wafer W installed on the stage 12.

The conveying means 13 houses the wafer W that has been turned over by the wafer reversing mechanism 22, and conveys the wafer W sequentially to the plurality of treatment units 14. Specifically, as illustrated in FIG. 5, the conveying means 13 includes a conveying arm 31, a holder 32 that is a holding assembly as a holding unit, an arm rotation drive unit 33, an arm vertical movement drive unit 34, and a wafer rotation drive unit 35. The conveying arm 31 is installed with the longitudinal direction thereof directed toward the horizontal direction, and is rotated by the arm rotation drive unit 33 along the bottom surface of the plating chamber 11 around the proximal end side thereof, which is located at the center position of the stage 12.

The arm rotation drive unit 33 rotates and drives the conveying arm 31 around the other end side of the conveying arm 31 in an arc within a predetermined angle range. In other words, the arm rotation drive unit 33 moves the conveying arm 31 in an arc in a horizontal plane, and for example, formed with a robot rotary. On the arm rotation drive unit 33, the arm vertical movement drive unit 34 is mounted, and the proximal end side of the conveying arm 31 is connected to the arm vertical movement drive unit 34 is that the conveying arm 31 can be moved in the vertical direction, namely, upward and downward.

The wafer rotation drive unit 35 is mounted to the upper side of the distal end portion of the conveying arm 31, and for example, is formed with a motor. The wafer rotation drive unit 35 rotates and drives a rotary shaft 36 serving as a cylindrical support assembly, which projects downward from the lower surface of the distal end portion of the conveying arm 31, in the circumferential direction. The holder 32 is supported around an axis thereof by the rotary shaft 36, and when the wafer rotation drive unit 35 rotates the rotary shaft 36 therearound, the holder 32 is rotated around the center position thereof.

The holder 32 is mounted to one end side of the conveying arm 31, and as illustrated in FIG. 5 to FIG. 8, consists of a lower part 37 and an upper part 38 which can be separated in the vertical direction. As illustrated in FIG. 7 and FIG.8, the lower part 37 includes a housing recess 41 having a top surface that is opened and a bottom surface on which the wafer W can be placed. The housing recess 41 is formed in a bottomed cylindrical shape having the inside diameter substantially equal to the outside diameter of the wafer W. The bottom surface of the housing recess 41 is provided with a concentric opening 42 having the inside diameter slightly smaller than the outside diameter of the wafer W. On the inner peripheral edge of the bottom surface of the housing recess 41, a circular O-ring 43 used to seal the wafer W is mounted. The O-ring 43 seals, in a state where the wafer W is placed on the bottom surface of the housing recess 41, the outer peripheral edge portion of the surface B to be treated of the wafer W in the circumferential direction.

The side surface of the housing recess 41 includes a pressure adjustment hole 44 for equalizing the pressure in the housing recess 41 and the pressure outside the housing recess 41. Furthermore, on the opening edge of the housing recess 41, a disc-shaped covering piece member 45 which projects outward from the outer peripheral surface of the housing recess 41 is mounted concentrically. On the outer peripheral edge of the covering piece member 45, an annular circumferential surface member 46 that projects upward is mounted concentrically. Furthermore, on an intermediate position in the vertical direction of the circumferential surface member 46, an engagement recess 47 serving as a locking member having a recessed cross-section is mounted over the circumferential direction of the circumferential surface member 46. Inside the circumferential surface member 46, a magnetic assembly 48 formed with, for example, iron is provided. The magnetic assembly 48 is provided with, at a center position. thereof, an opening 49 having a circular shape that is substantially equal to the inside diameter of the housing recess 41, and is formed in an annular shape having the outside diameter substantially equal to the inside diameter of the circumferential surface member 46.

As illustrated in FIG. 6 to FIG. 7, the upper part 38 includes a bottomed cylindrical insertion projection 51 that can be inserted into and removed from the housing recess 41 of the lower part 37. The insertion projection 51 is formed to have the outside diameter substantially equal to the inside diameter of the housing recess 41. Furthermore, the insertion projection 51 sandwiches, in a state of being inserted into the housing recess 41 of the lower part 37, the wafer W placed on the bottom surface of the housing recess 41 with the bottom surface of the housing recess 41. Inside the insertion projection 51, an electrode unit 52 for energizing the wafer W is provided. The electrode unit 52 is housed in the insertion projection 51 with its tip projecting downward from the lower end surface of the insertion projection 51, and energizes the wafer W placed on the bottom surface of the housing recess 41 in a state where the insertion projection 51 is inserted into the housing recess 41.

On the peripheral surface of the insertion projection 51, an O-ring 53 for sealing the inner peripheral surface of the housing recess 41 and the outer peripheral surface of the insertion projection 51 is mounted. The O-ring 53 seals the inside of the housing recess 41 in a state where the insertion projection 51 is inserted into the housing recess 41. Therefore, the O-rings 43, 53 serve as a sealing means for sealing the space in the housing recess 41 in a state where the wafer is placed on the bottom surface of the housing recess 41 and the insertion projection is inserted into the housing recess 41.

Furthermore, the upper end of the insertion projection 51 is provided with a concentrical disc-shaped support piece member 54 that is substantially equal to the outside diameter of the circumferential surface member 46 of the lower part 37. On the lower surface of the support piece member 54, an annular magnet assembly 55 is embedded and mounted concentrically. The magnet assembly 55 is mounted such that its lower surface is made flush with the lower surface of the support piece member 54. On the upper surface side of the support piece member 54, the lower end of the rotary shaft 36 of the wafer rotation drive unit 35 is fixed and mounted concentrically. Thus, the magnetic assembly 48 and the magnet assembly 55 serve as an integrating means for removably integrating the lower part 37 with the upper part 38.

The plurality of treatment units 14 is arranged at predetermined intervals on the rotation trajectory of the holder 32 which is obtained in accordance with the rotation drive by the reversing arm 23 of the conveying means 13. The pre-treatment unit 14a includes a pre-treatment tank 61 which is a bottomed cylindrical treatment tank filled with the plating solution M as a treatment liquid. The pre-treatment tank 61 has the inside diameter larger than the outside diameter of the housing recess 41 of the lower part 37 of the holder 32. The pre-treatment tank 61 is filled with the plating solution M, and the lower end side of the housing recess 41 of the holder 32 is immersed in the plating solution M. In this state, in the pre-treatment tank 61, the pre-treatment process is performed for the surface B to be treated of the wafer 4 which is exposed through the opening 42 of the housing recess 41 of the holder 32, for example, to remove air bubbles in the plating solution M adhering to the surface B to be treated of the wafer W.

As illustrated in FIG. 8, the plating member 14b includes a plating tank 62 that is a treatment tank used to plate the surface B to be treated of the wafer W, for example, with Cu. The plating tank 62 is filled with the plating solution N that is the same as the plating solution M filling the pre-treatment tank 61. The plating tank 62 includes a top surface that is opened, and is formed to have the outside diameter substantially equal to the outside diameter of the covering piece member 45 of the lower part 37 of the holder 32 so that the top surface of the plating tank 62 can be covered with the covering piece member 45 of the lower part 37. On the opening edge of the top surface of the plating tank 62, an annular rubber packing 63 is mounted concentrically so as to cover the top surface of the plating tank 62 in the circumferential direction. Furthermore, the plating tank 62 includes an opening 64 used to adjust the pressure in the plating tank 62. On the opening 64, a decompression pump (not illustrated) that is a decompression means for reducing the pressure in the plating tank 62 through the opening 64 is mounted. The decompression pump adjusts the pressure difference between the pressure in the housing recess 41 sealed by the O-ring 53 and the pressure of the plating solution M filling the plating tank 62. That is, the decompression pump serves as a pressure adjustment means for adjusting the pressure difference between. the pressure in the housing recess 41 and the pressure of the plating solution M in the plating tank 61 by using the pressure adjustment hole 44, the rubber packing 63, and the opening 64.

Furthermore, as illustrated in FIG. 9, on the plating tank 62, a circulation mechanism 66 for circulating the plating solution M filling the plating tank 62 is mounted. The circulation mechanism 66 includes a reservoir tank 66a that is a plating solution tank storing a predetermined amount of, for example, one liter of the plating solution M. On the reservoir tank 66a, a pump 66b for pumping up the plating solution M stored in the reservoir tank 66a is mounted. On the pump 66b, a solution drawing pipe 66c for supplying the plating solution M pumped up by the pump 66b into the plating tank 62 is mounted. The solution drawing pipe 66c includes a nozzle unit 66d inserted into and mounted to the plating tank 62. The nozzle unit 66d is mounted to a position facing the surface B to be treated of the wafer W which is to be immersed in the plating solution M of the plating tank 62 so as to directly supply the plating solution M ejected from the nozzle unit 66d to the surface B to be treated of the wafer W. Furthermore, on the plating tank 62, an overflow tank 66e is mounted. The overflow tank 66e is designed to, when the plating solution M in the plating tank 62 exceeds a predetermined amount, receive the plating solution M overflown and discharged from the plating tank 62. On the overflow tank 66e, a solution returning pipe 66f for returning the plating solution N which has overflown into the overflow tank 66e to the reservoir tank 66a is mounted.

As illustrated in FIG. 3, a suction port 67 is provided around the plating tank 62. The suction port 67 is, used to discharge, from the plating chamber 11, the plating solution M in the form of a mist to be drained from the surface B to be treated of the wafer W manly during the pre-treatment process by the pre-treatment unit 14a or the plating process by the plating unit 14b. The suction port 67 is connected to the scrubber 2j. The scrubber 2j forcibly sucks chemicals such as the plating solution M in the form of a mist floating within the plating chamber 11 and discharges it to the outside of the plating chamber 11.

As illustrated in FIG. 3, the water washing unit 14c includes a water washing tank 71 which is a bottomed cylindrical treatment tank having the inside diameter larger than the outside diameter of the housing recess 41 of the holder 32. The water washing tank 71 is provided with an opening 72 at the center position of the lower surface thereof. On the opening 72, a pure water supply mechanism (not illustrated) for supplying pure water that is a treatment liquid is mounted. The pure water supply mechanism supplies the pure water into the water washing tank 71 through the opening 72 so that the surface B to be treated of the wafer W inserted into the water washing tank 71 is washed with the water. When the pure water supplied to the water washing tank 71 overflows from the water washing tank 71, the overflown water is discharged to the outside of the plating chamber 11 from a drain port 73 provided around the water washing tank 71.

The post-treatment unit 14d is designed substantially in the same manner as the water washing unit 14c, and includes a post-treatment tank 74 which is a bottomed cylindrical treatment tank having the inside diameter larger than the outside diameter of the housing recess 41 of the holder 32. The post-treatment tank 74 is provided with an opening 75 at the center position of the lower surface thereof. On the opening 75, a post-treatment solution supply mechanism (not illustrated) for supplying the post-treatment solution that is a treatment liquid is mounted. Here, as the post-treatment solution, for example, an anti-rust treatment material for covering a protective film, such as an organic film, on the plating layer formed on the surface B to be treated of the wafer W is used. In the post-treatment unit 14d, the post-treatment solution supply mechanism supplies the post-treatment solution into the post-treatment tank 74 through the opening 75 so as to form the protective film on the plating layer formed on the surface B to be treated of the wafer W which has been inserted into the post-treatment tank 74. When the post-treatment solution supplied in the post-treatment tank 74 overflows from the post-treatment tank 74, the overflown solution is discharged to the outside of the plating chamber 11 from the drain port 73 provided around the post-treatment tank 74.

The drying unit 14e includes a drying tank 76 which is a bottomed cylindrical treatment tank having the inside diameter larger than the outside diameter of the housing recess 41 of the holder 32. The drying tank 76 is provided with an opening 77 at the center position. of the lower surface thereof, and on the opening 77, a warm air supply mechanism. (not illustrated) for supplying warm air of, for example, 45° C. is mounted. The warm air supply mechanism supplies the warm air into the drying tank 76 through the opening 77 to dry the protective film on the surface B to be treated of the wafer W which has been inserted into the drying tank 76.

As illustrated. in FIG. 3, the wafer housing unit 14f is a standby port on which the lower part 37 of the holder 32 is installed. The wafer housing unit 14f conveys the wafer W which has been reversed upside down by the wafer reversing mechanism 22 to the housing recess 41 of the lower part 37 installed on the wafer housing unit 14f so as to house the wafer W in the housing recess 41. As illustrated in FIG. 10A to FIG. 10F, the wafer housing unit 14f includes a chuck mechanism 78, which is to be engaged with the engagement recess 47 of the lower part 37 provided on the wafer housing unit 14f and serves as a removal means for removing the upper part 38 from the lower part 37. The chuck mechanism 78 includes an engagement piece member 79 serving as a radially movable locked unit, and a drive mechanism (not illustrated) for moving the engagement piece member 79 in the radial direction. In the chuck mechanism 78, in a state where the lower part 37 is installed on the wafer housing unit 14f, the drive mechanism moves the engagement piece member 79 in the direction toward the central axis to make the engagement piece member 79 engage with the engagement recess 47 of the lower part 37. Furthermore, in the chuck mechanism 78, in a state where the upper part 38 is separated from the lower part 37, the driving mechanism moves the engagement piece member 79 in the radial direction to release the engagement between the engagement recess 47 of the lower part 37 and the engagement piece member 79.

As illustrated in FIG. 3, the plating chamber 11 includes a partition plate 81 that partitions the plating chamber 11 into two regions. The partition plate 81 separates, from the other places in the plating chamber 11, a chemical floating region 82 in which the chemical solution in the form of a mist is generated. Specifically, the chemical floating region 82 includes the places where the pre-treatment unit 14a, the plating unit 14b, the drain port 73, the water washing unit 14c, and the post-treatment unit 14d are mounted. In other words, the partition plate 81 partitions, from the chemical floating region 82, the wafer transfer path from the PLAD system 9 to the stage 12, the wafer transfer path from the stage 12 to the wafer housing unit 14f, and the installation position of the drying unit 14e, namely, a non-chemical floating region 83. On the other hand, the partiton plate 81 is provided with an opening 84 through which the holder 32 is conveyed from the wafer housing unit 14f to the pre-treatment unit 14a, the plating unit 14b, the water washing unit 14c, and the post-treatment unit 14d.

### <Operations>

Hereinafter, a plating method using the plating machine 1 according to the embodiment described above will be explained.

### (Conveying Process)

Firstly, the shuttle in which the wafer W is housed with the surface B to be treated facing upward is fitted to the docking port 2e of the front chamber 2d of the housing 2, and installed thereon. In this state, a start switch which is, for example, displayed on a predetermined position of the housing 2, such as the operation panel 2c, is turned on (not illustrated).

In response thereto, the fan 2g attached. to the upper portion of the housing 2 is driven, whereby the air out the housing 2 is sucked from the air vent 2f, particles contained in the air sucked from the air vent 2f are captured by the air filter 2h, and the air of which the particles has been removed is supplied to the housing 2. At the same time, the scrubber 2j mounted to the lower portion of the housing 2 is driven, whereby the air floating in the chemical floating region 82 of the plating chamber 11 is forcibly sucked from the suction port 67 and discharged from the discharge outlet 2k to the outside of the housing 2. At this time, as illustrated in FIG. 11, in the plating chamber 11, the air outside the plating chamber 11 is supplied from the non-chemical floating region 83 to the chemical floating region 82 via the opening 84, and then discharged from the suction port 67 to the outside of the plating chamber 11. Thus, as illustrated in FIG. 12, the pressure of the plating chamber 11 becomes negative as compared with the pressures in the other areas in the housing 2 so that the air in the plating chamber 11 cannot be released into the housing 2.

Thereafter, the shuttle installed on the docking port 2e is released. Then, the wafer N housed in the shuttle, with the surface B to be treated facing upward, is conveyed by the PLAD system 9 onto the stage 12 in the plating chamber 11 as illustrated in FIG. 4A.

### (Wafer Reversing Process)

Next, the vertical movement drive unit 26 of the wafer reversing mechanism 22 moves the reversing arm 23 upward to bring the lower surface of the wafer W into contact with the suction pad 24 and make the wafer W sucked thereto. Thereafter, as illustrated in FIG. 4B, the vertical movement drive unit 26 moves the reversing arm 23 further upward so that the wafer W sucked on the suction pad 24 is moved above the stage 12.

In this state, the rotation drive unit 25 rotates the reversing arm 23 by 180 degrees around the proximal end side of the reversing arm 23. As a result, as illustrated in FIG. 4C, the surface B to be treated of the wafer N sucked on the suction pad 24 faces downward, and the surface B to be treated of the wafer W is positioned to face the housing recess 41 of the lower part 37 of the holder 32 installed in the wafer housing unit 14f. Then, as illustrated in FIG. 4D, the vertical movement drive unit 26 moves the reversing arm 23 downward to bring and place the wafer W sucked on the suction pad 24 into the housing recess 41 of the lower part 37. Thereafter, the suction between the wafer N and the suction pad 24 is released. After the vertical movement drive unit 26 moves the reversing arm 23 upward, the rotation drive unit 25 rotates the reversing arm 23 by 180 degrees in the reversing direction, and then the vertical movement drive unit 26 moves the reversing arm 23 downward. Thus, as illustrated in FIG. 4A, the initial state in which the stage 12 houses the suction pad 24 is restored.

### (Wafer Housing Process)

Next, as illustrated in FIG. 10A, the arm rotation drive unit 33 of the conveying means 13 moves the upper part 38 of the holder 32 to a position facing the lower part 37 installed on the wafer housing, unit 14f. In this state, as illustrated in FIG. 10B, the arm vertical movement drive unit 34 moves the upper part 38 downward to fit the insertion projection 51 of the upper part 38 into the housing recess 41 of the lower part 37. At this time, the wafer W which has been placed on the bottom surface of the housing recess 41 is sandwiched between the insertion projection 51 of the upper part 38 and the bottom surface of the housing recess 41. Accordingly, the wafer W allows the surface B to be treated to be exposed toward the lower side through the opening 42 of the lower part 37 and comes into contact with the electrode unit 52 of the upper part 38 to be energized. Furthermore, due to the magnetic force between the magnetic assembly 48 f the lower part 7 and the magnet assembly 55 of the upper part 38, the lower part 37 is integrated with. the upper part 38. Furthermore, the O-ring 43 of the lower part 37 presses the outer peripheral edge of the surface B to be treated of the wafer W against the bottom side of the housing recess 41, whereby a sealed state is generated.

### (Pre-Treatment Process)

Thereafter, as illustrated in FIG. 10C, the arm vertical movement drive unit 34 of the conveying means 13 moves the holder 32, in which the upper part 38 is integrated with the lower part 37, upward. Then, the arm rotation drive unit 33 rotates the conveying arm 31 in an arc to convey the holder 32 onto the pre-treatment tank 61. In this state, the arm vertical movement drive unit 34 moves the holder 32 downward to immerse the surface B to be treated of the wafer W which is exposed through the opening 42 of the lower part 37 of the holder 32 in the plating solution N filling the pre-treatment tank 61. At this time, since the wafer rotation drive unit 35 rotates the holder 32 and the inside of the plating chamber 11 is decompressed, air bubbles in the plating solution M adhering to the surface B to be treated of the wafer W are removed. Thereafter, the arm vertical movement drive unit 34 moves the holder 32 upward to take out the surface B to be treated which is exposed through the opening 42 of the lower part 37 of the holder 32 from the plating solution M in the pre-treatment tank 61. Then, the wafer rotation drive unit 35 rotates the holder 32 at high speed in the circumferential direction to drain the plating solution M to an extent that does not fall off from the surface B to be treated of the wafer W.

### (Plating Process)

Thereafter, the arm rotation drive unit 33 rotates the conveying arm 31 in an arc to convey the holder 32 onto the plating tank 62. At this time, as illustrated in FIG. 9, the pump 66b of the circulation mechanism 66 is driven, whereby the plating solution M in the reservoir tank 66a is supplied from the nozzle unit 66d to the plating tank 62 through the solution. drawing pipe 66c. When exceeding a predetermined amount, the plating solution M in the plating tank 62 overflows to the overflow tank 66e, and returns to the reservoir tank 66a through the solution returning pipe 66f.

Then, in a state where the circulation mechanism 66 keeps circulating the plating solution M in the plating tank 62, the arm vertical movement drive unit 34 moves the holder 32 downward to immerse the surface B to be treated of the wafer W which is exposed from the opening 42 of the lower part 37 of the holder 32 in the plating solution M of the plating tank 62. At this time, as illustrated in FIG. 8, the decompression pump is driven to discharge the air in the plating tank 62 from the opening 64, and also discharge the air in the housing recess 41 f the holder 32 from the pressure adjustment hole 44, so that the pressure of the plating solution M in the plating tank 62 is adjusted to be equal to the pressure in the housing recess 41 of the lower part 37 of the holder 32.

In this state, the wafer rotation. drive unit 35 rotates the holder 32 in the circumferential direction, and the wafer W is supplied with. power from the electrode unit 52 of the upper part 38 of the holder 32 to generate a potential difference between the wafer W and the plating tank 62, whereby a plating layer formed on the surface B to be treated of the wafer W. Thereafter, the arm vertical movement drive unit 34 moves the holder 32 upward to take the surface B to be treated which is exposed through the opening 42 of the lower part 37 of the holder 32 out from the plating solution M in the plating tank 62. Then, the wafer rotation drive unit 35 rotates the holder 32 at high speed in the circumferential direction to drain the plating solution M adhering to the surface B to be treated of the wafer W.

### (Water Washing Process)

Thereafter, the arm rotation drive unit 33 rotates the conveying arm 31 in an arc to convey the holder 32 onto the water washing tank 71. In this state, the arm vertical movement drive unit 34 moves the holder 32 downward to bring the surface B to be treated of the wafer W which is exposed through the opening 42 of the lower part 37 of the holder 32 into the water washing tank 71. Then, the pure water supply mechanism supplies the pure water into the water washing tank 71 through the opening 72 of the water washing tank 71, and also the wafer rotation drive unit 35 rotates the holder 32 in the circumferential direction so as wash the plating layer formed on the surface B to be treated of the wafer W with the pure water. At this time, the pure water which overflows from the water washing tank 71 is discharged to the outside of the plating chamber 11 through the drain port 73.

Thereafter, the arm vertical movement drive unit 34 moves the holder 32 upward to take the surface B to be treated which is exposed through the opening 42 of the lower part 37 of the holder 32 out from the water washing tank 71. Then, the wafer rotation drive unit 35 rotates the holder 32 at high speed in the circumferential direction to drain the pure water adhering to the plating layer formed on the surface B to be treated of the wafer W.

### (Post-Treatment Process)

Furthermore, the arm rotation drive unit 33 rotates the conveying arm 31 in an arc to convey the holder 32 onto the post-treatment tank 74. In this state, the arm vertical movement drive unit 34 moves the holder 32 downward to immerse the surface B to be treated of the wafer W which is exposed through the opening 42 of the lower part 37 of the holder 32 into the post-treatment solution filling the post-treatment tank 74. At this time, the wafer rotation drive unit 35 rotates the holder 32 in the circumferential direction to make the post-treatment solution adhering to the plating layer formed on the surface B to be treated of the wafer W.

Thereafter, the arm vertical movement drive unit 34 moves the holder 32 upward to take the surface B to be treated which is exposed through the opening 42 of the lower part 37 of the holder 32 out from the post-treatment solution in the post-treatment tank 74. Then, the wafer rotation drive unit 35 rotates the holder 32 in the circumferential direction to form a protective film by drying and curing the post-treatment solution adhering to the plating layer of the wafer W.

### (Water Washing Process)

Next, the arm rotation drive unit 33 rotates the conveying arm 31 in an arc to convey the holder 32 onto the water washing tank 71, and the arm vertical movement drive unit 34 moves the holder 32 downward to insert the lower end of the holder 32 into the water washing tank 71. Thereafter, the pure water supply mechanism supplies the pure water through the opening 72 of the water washing tank 71 into the water washing tank 71, and the wafer rotation drive unit 35 rotates the holder 32 in the circumferential direction so as to wash the protective film of the wafer W with water.

Thereafter, the arm vertical movement drive unit 34 moves the holder 32 upward to take the surface B to be treated which is exposed through the opening 42 of the lower part 37 of the holder 32 out from the water washing tank 71. Then, the wafer rotation drive unit 35 rotates the holder 32 at high speed in the circumferential direction so as to drain the pure water adhering to the protective film of the wafer W.

### (Drying Process)

Next, the arm rotation drive unit 33 rotates the conveying arm 31 in an arc to convey the holder 32 onto the drying tank 76. In this state, the arm vertical movement drive unit 34 moves the holder 32 downward to insert the surface B to be treated of the wafer W which is exposed through the opening 42 of the lower part 37 of the holder 32 into the drying tank 76. Thereafter, the warm air supply mechanism supplies the warm air to the drying tank 76 through the opening 77 of the drying tank 76, and the wafer rotation drive unit 35 rotates the holder 32 at high speed in the circumferential direction so as to dry the wafer W.

At this time, as illustrated in FIG. 13, while the warm air supply mechanism supplies the warm air to the drying tank 76 through the opening 77 of the drying tank 76, the scrubber 2j is driven and thus the air in the chemical floating region 82 is discharged through the suction port. 67, whereby the air in the non-chemical floating region 83 flows toward the chemical floating region 82 through the opening 84, and then is discharged to the outside of the plating chamber 11. As a result, as illustrated in FIG. 14, the pressure in the non-chemical floating region 83 becomes positive more than that in the outside of the housing 2 and that in the chemical floating region 62, which functions as an exclusion system for suppressing the invasion of chemicals, particles, or the like from the chemical floating region 82 and the outside of the housing 2.

Thereafter, the arm vertical movement drive unit 34 moves the holder 32 upward to take the surface B to be treated which is exposed through the opening 42 of the lower part 37 of the holder 32 out from the drying tank 76.

### (Carrying Out Process)

Next, the arm rotation drive unit 33 rotates the conveying arm 31 in an arc to convey the holder 32 onto the wafer housing unit 14f. Thereafter, as illustrated in FIG. 10D, the arm vertical movement drive unit 34 places the holder 32 on the wafer housing unit 14f. Then, as illustrated in FIG. 10E, the drive mechanism moves the engagement piece member 79 of the chuck mechanism 78 in the direction toward the central axis to engage the engagement piece member 79 with the engagement recess 47 of the lower part 37 of the holder 32. In this state, as illustrated in FIG. 10F, the arm vertical movement drive unit 34 moves the upper part 38 upward against the magnetic force between the magnetic assembly 48 of the lower part 37 and the magnet assembly 55 of the upper part 38 to release the integration of the lower part 37 with the upper part 38 which has been made by the magnetic force between the magnetic assembly 48 and the magnet. assembly 55. Whereby the upper part 38 is removed from the lower part 37.

In this state, the vertical movement drive unit 26 of the wafer reversing mechanism 22 moves the reversing arm 23 upward, and then. the rotation drive unit 25 rotates the reversing arm 23 by 180 degrees around the proximal end side of the reversing arm 23. Thereafter, the vertical movement drive unit 26 moves the reversing arm 23 downward so as to, as illustrated in FIG. 4D, bring the suction pad 24 into contact with the top surface of the wafer W placed on the housing recess 41 of the lower part 37 and make the wafer W sucked to the suction pad 24. Then, the vertical movement drive unit 26 moves the reversing arm 23 upward, and the rotation drive unit 25 rotates the reversing arm 23 by 180 degrees in the reverse direction. Thereafter, the vertical movement drive unit 26 moves the reversing arm 23 downward so as to, as illustrated in FIG. 4A, place the wafer W on the stage 12 with the surface B to be treated facing upward.

Thereafter, the PLAD system 9 carries out the wafer W placed on the stage 12 to place the wafer W on the shuttle installed in the docking port 2e. The shuttle is closed to house the wafer W, and removed from the docking port 2e of the front chamber 2d, whereby the wafer W is carried out.

### <Effect>

As described. above, in the plating machine 1 according to the embodiment, on the rotation trajectory of the center position of the holder 32 which is obtained by the arcuate rotation of the conveying arm 31 by the arm rotation drive unit 33, each of the plurality of treatment units 14, namely, the pre-treatment tank 61, the plating tank 62, the water washing tank 71, and the post-treatment tank 74, and the wafer housing unit 14f that is a standby port of the lower part 37 of the holder 32 are arranged at the predetermined intervals. The wafer W is placed on the housing recess 41 of the lower part 37 installed. on the wafer housing unit 14f, and then the arm vertical movement drive unit 34 moves the upper part 38 downward. to immerse the insertion projection 51 of the upper part 38 into the housing recess 41 of the lower part 37, whereby the lower part 37 is integrated with the upper part 38 to be the holder 32. With a simple structure and through a simple operation. in which the arm rotation drive unit 33 rotates the conveying arm 31 in an arc in the state above, it is possible to convey the wafer W held by the holder 32 sequentially with a relatively short moving distance to each of the pre-treatment tank 61, the plating tank 62, the water washing tank 71, and the post-treatment tank 74. Furthermore, through the rotary operation of the holder 32 interlocked with the convey operation of the wafer W to the pre-treatment tank 61, the plating tank 62, the water washing tank 71, and the post-treatment tank 74, it is possible to carry the holder 32 in and out from the wafer housing unit 14f.

In particular, the wafer W is placed on the bottom surface of the housing recess 41 of the lower part 37 of the holder 32 with the surface B to be treated facing downward, so that the surface B to be treated of the wafer W is exposed through the opening 42 of the housing recess 41. In this state, the insertion projection 51 of the upper part 38 is inserted into the housing recess 41 of the lower part 37 to integrate the lower part 37 with the upper part 38, whereby the wafer W is sandwiched between the insertion projection 51 of the upper part 38 and the opening edge of the housing recess 41 of the lower part 37. Then, since the arm vertical movement drive unit 34 moves the holder 32 downward to immerse the lower end of the housing recess 41 of the lower part 37 of the holder 32, for example, in the plating solution M in the plating tank 62, it is possible to accurately and reliably immerse the surface B to be treated which is exposed through the opening 42 of the lower part 37 of the holder 32 into the plating solution M. Thus, it is possible to accurately and reliably plate the surface B to be treated of the wafer W.

Furthermore, in the state where the wafer W is placed on the bottom surface of the housing recess 41 of the lower part 37 of the holder 32, the insertion projection 51 of the upper part 38 is inserted into the housing recess 41 to integrate the lower part 37 with the upper part 38, whereby the electrode unit 52 of the upper part 38 is brought in contact with the top surface of the wafer W and energizes the wafer W. Thus, only through a series of operations of placing the wafer W on the housing recess 41 of the lower part 37 of the holder 32 and inserting the insertion projection 51 of the upper part 38 into the housing recess 41, it is possible to easily secure an electrode for the wafer W, which is required during the plating process.

Furthermore, after the wafer W is placed on the bottom surface of the housing recess 41 of the lower part 37 of the holder 32 with the surface B to be treated of the wafer W facing downward so that the surface B to be treated of the wafer W is exposed through the opening 42 of the lower part 37 of the holder 32, the arm rotation drive unit 33 rotates the conveying arm 31 in an arc to convey the holder 32 onto any one of the pre-treatment tank 61, the plating tank 62, the water washing tank 71, and the post-treatment tank 74. In this state, the arm vertical movement drive unit 34 moves the holder 32 upward and downward to take the wafer W held by the holder 32 in and out from any one of the pre-treatment tank 61, the plating tank 62, the water washing tank 71, and the post-treatment tank 74. Thus, only through the operation of moving the holder 32 vertically by the arm vertical movement drive unit 34, it is possible to realize the operations of immersing, inserting and taking out the surface B to be treated of the wafer W held by the holder 32 with respect to the pre-treatment tank 61, the plating tank 62, the water washing tank 71, and the post-treatment tank 74. As a result, the operation of conveying the wafer 4 and the structure necessary for conveying the wafer W can be simplified. Furthermore, since only the surface B to be treated of the wafer 7 which is exposed through the opening 42 of the lower part 37 of the holder 32 is plated, it is possible to simplify the plating process for the wafer 71 which is performed by the plurality of treatment units 14.

In particular, when the arm vertical movement drive unit 34 moves the holder 32 downward to immerse the lower end of the housing recess 41 of the lower part 37 of the holder 32, for example, in the plating solution M in the plating tank 62, as illustrated in FIG. 8, the opening edge of the plating tank 62 is covered with the covering piece member 45 of the lower part 37. Therefore, in the case of plating the wafer W by immersing the lower end portion of the housing recess 41 of the lower part 37 of the holder 32 in the plating solution M of the plating tank 62, it is possible to prevent spillage of the plating solution from the opening edge of the plating tank 62 to the outside of the plating tank 62.

Furthermore, in the plating unit 14b, the arm vertical movement drive unit 34 moves the holder 32 downward to immerse the lower end of the housing recess 41 of the holder 32 in the plating solution M of the plating tank 62. Then, as illustrated in FIG. 8, the covering piece member 45 of the lower part 37 of the holder 32 is brought into contact with the rubber packing 63 mounted to the opening edge of the plating tank 62. In. this state, the decompression pump is driven to discharge the air in the plating tank 62 from the opening 64 so that the covering piece member 45 of the lower part 37 of the holder 32 is pressed against the rubber packing 63 mounted to the opening edge of the plating tank 62, and thus the plating tank 62 is brought into an airtight state. Furthermore, since the air in the housing recess 41 of the holder 32 is discharged from the pressure adjustment hole 44, the pressure of the plating solution M in the plating tank 62 becomes equal to the pressure in the housing recess 41 of the lower part 37 of the holder 32. Thus, the pressure difference between the pressure in the housing recess 41 and the pressure of the plating solution N can be eliminated, and as a result, it is possible to accurately prevent, with a simple structure, the entry of the plating solution M from the opening 42 of the housing recess 41 of the lower part 37 which is caused by the pressure difference.

Furthermore, in the state where the wafer W is placed on the bottom surface of the housing recess 41 of the lower part 37 of the holder 32 and then the insertion projection 51 of the upper part 38 is inserted into the housing recess 41 of the lower part 37 to integrate the lower part 37 with the upper part 38, the wafer rotation drive unit 35 rotates the holder 32 in the circumferential direction to rotate the wafer W held by the holder 32. Thus, through the same operation of rotating the holder 32 by the wafer rotation drive unit 35, it is possible to drain the plating solution M adhering to the surface B to be treated during the pre-treatment process, drain the plating solution M adhering to the surface B to be treated during the plating process, drain the pure water adhering to the plating layer of the wafer W during the water washing process, dry the post-treatment solution adhering to the plating layer of the wafer W during the post-treatment process, drain the pure water adhering to the protective film of the wafer during the water washing process, and dry the wafer W during the drying process.

Furthermore, since the wafer W is placed on the bottom. surface of the housing recess 41 of the lower part 37 of the holder 32 after the wafer reversing mechanism 22 reverses the surfaces of the wafer W upside down, the wafer W can be housed on the bottom surface of the housing recess 41 of the lower part 37 in a state where the surface B to be treated of the wafer, which had. been conveyed onto the stage 12 with the surface B to be treated facing upward, has been reversed by the wafer reversing mechanism 22 so as to face downward. This causes the surface B to be treated of the wafer W to be exposed through the opening 42 of the lower part 37, and when the lower end of the housing recess 41 of the lower part 37 of the holder 32 is inserted into the pre-treatment tank 61, the plating tank 62, or the post-treatment tank 74, the surface B to be treated of the wafer W can be immersed in the plating solution M filling the pre-treatment tank 61 and the plating tank 62 or the post-treatment solution filling the post-treatment tank 74. As a result, only through the operation of moving the holder 32 upward and downward by the arm vertical movement drive unit 34, it is possible to easily perform the processes of pre-treatment, plating, and post-treatment for the surface B to be treated of the wafer W held by the holder 32.

Furthermore, the wafer W housed in the shuttle with the surface B to be treated facing upward is taken out from the shuttle while the surface B to be treated remains facing upward, and then the PLAD system 9 conveys the wafer W to the stage 12 in a state where the lower surface of the wafer W is supported thereby. Then, after the wafer reversing mechanism 22 reverses the front and back surfaces of the wafer W which has been conveyed to the stage 12 so as to make the surface B to be treated face downward, the wafer W is placed on the housing recess 41 of the lower part 37 of the holder 32. Thus, the operations during which the wafer W is taken out from the shuttle and conveyed to the stage 12 are performed by the PLAD system 9 in such a way that a portion other than the surface B to be treated, namely, the lower surface of the wafer W is held thereby, and accordingly, it is possible to convey the wafer W without allowing the surface B to be treated to be touched. Furthermore, the operations during which the wafer W is conveyed from the stage 12 and placed Jr on housing recess 41 of the holder 32 are performed in such a way that the wafer W is housed in the housing recess 41 of the lower part 37 after the back surface of the wafer W is sucked by the suction pad 24 and turned over by the wafer reversing mechanism 22. Thus, only through the operations of making the surface other than the surface B to be treated of the wafer W, namely, the lower surface sucked. t the suction pad 24 and then reversed, the wafer W is housed in the housing recess 41. Accordingly, the wafer W can be inserted into the housing recess 41 without allowing the surface B to be treated to be touched.

Similarly, the operations during which the wafer W is taken. out from. the housing recess 41 of the lower part 37 and conveyed onto the stage 12 are performed in such a way that the wafer W is conveyed. to the stage 12 after the surface other than the surface B to be treated, namely, the back surface is sucked by the suction pad 24 and turned over, and accordingly, it is possible to convey the wafer W without allowing the surface B to be treated to be touched by the suction pad 24. Furthermore, the operations during which the wafer W is conveyed from the stage 12 and placed onto the shuttle are performed by the PLAD system 9 in such a way that the lower surface of the wafer W is held thereby, and accordingly, it is possible to convey the wafer W without allowing the surface B to be treated to be touched. Thus, in each of the operations during which the wafer W is conveyed from the shuttle and placed on the bottom surface of the housing recess 41 of the lower part 37 of the holder 32, and the operations during which wafer W is taken out from the housing recess 41 of the lower part 37 and housed in the shuttle, it is possible to reliably prevent the surface B to be treated from being damaged during convey of the wafer W.

In particular, after the process of plating the surface B to be treated, the arm rotation drive unit 33 rotates the conveying arm 31 in an arc to convey the holder 32 to the wafer housing unit 14f, and then the arm vertical movement drive unit 34 moves the conveying arm 31 downward to place the lower part 37 of the holder 32 on the wafer housing unit 14f. In this state, the drive mechanism moves the engagement piece member 79 of the chuck mechanism 78 in the direction toward the central axis, as illustrated in FIG. 10E, to engage the engagement piece member 79 with the engagement recess 47 of the lower part 37 of the holder 32. Then, the arm vertical movement drive unit 34 moves the upper part 38 upward against the magnetic force between the magnetic assembly 48 of the lower part 37 and the magnet assembly 55 of the upper part 38, as illustrated in FIG. 10F, to remove the upper part 38 from the lower part 37. Then, the wafer reversing mechanism 22 takes out the wafer W placed on the bottom surface of the housing recess 41 of the lower part 37 to allow the wafer W to be conveyed onto the stage 12.

Furthermore, since the wafer W has a disc-shape having the outside diameter of 12.5 mm, is possible to use this wafer W in a so-called minimal fab system. Similarly, since the plating machine 1 is provided for plating the wafer W, it is possible to use the plating machine 1 as a plating machine in a so-called minimal fab system.

### <Technical Problems>

The technical problems of plating machines are mainly, (1) making the film thickness of the plating layer formed by plating uniform and shortening the time required for plating, and (2) improving productivity. Among these technical problems, in order to solve the technical problem (1), it is necessary to accelerate the updating of the plating solution on a surface of an object to be treated such as a wafer or a substrate. As specific methods therefor, for example, (1A) stirring the plating solution (see, for example, Non-Patent Literature: Kadota et al., “High-speed plating technique for three-dimensionally mounted through electrode”, Journal of Institute of Electronics Packaging, Vol. 13, No. 3, pages 213 to 219 (2010)) or (1B) moving the object to be treated are possible approaches.

The possible methods for stirring the plating solution described in the approach (1A) above include, for example, (a1) a method of stirring the plating solution using a stirrer, (a2) a method of stirring the plating solution horizontally using a so-called squeegee (see, for example, Patent Literature: JP-A-2005-054206), (a3) a method of spraying the plating solution onto the object using a jet nozzle (see, for example, Patent Literatures: JP-A-2007-277676 and JP-A-2006-265709), and (a4) a method of circulating the plating solution as a high-speed flow (see, for example, Patent Literature: JP-A-2005-054206).

The possible methods for moving the object to be treated described in the approach (1B) above includes, for example, (b1) a method of linearly reciprocating the object to be plated in the plating solution (see, for example, Patent Literature 1) and (b2) a method of horizontally or vertically rotating the object to be treated in the plating solution (see, for example, Patent Literatures: JP-A-2004-300462 and JP-A-2010-265532). In this connection, it should be noted that, depending on the direction of rotating the object to be treated in the plating solution, there is a possibility that the rotational resistance received from the plating solution increases, which causes decrease of the stirring force.

Furthermore, as the solutions for the technical problem (2) above, methods of plating an object to be treated by continuous processes are possible approaches. These methods include, for example, (2A) a vertically and continuously conveying method in which an upper end of a substrate that is vertically standing is held and conveyed (see, for example, Patent Literature 1), or (2B) a horizontally conveying method using a robot or the like (see, for example, Patent Literature: JP-A-2003-171791).

Among these methods, the combination of (2A) the vertically and continuously conveying method with (a3) the method of spraying the plating solution onto the object to be treated using a nozzle, or the combination of (2A) with (b1) the method of linearly reciprocating the object to be treated may solve each of the technical problems (1) and (2). However, these combinations may reduce the stirring force of the plating solution, and thus there is a possibility that the plating solution cannot be appropriately stirred.

The combination of (2B) the horizontally conveying method with (a2) the method of stirring the plating solution using the squeegee, the combination of (2B) with (a3) the method of spraying the plating solution onto the object to be treated. using a let nozzle, the combination of (2B) with (a4) the method of circulating the plating solution at high speed, or the combination of (2B) with (b2) the method of rotating the object to be treated in the plating solution may be possible. However, these combinations are based on the horizontally conveying method, and accordingly, it is necessary to fill and discharge the plating solution every time the object to be treated is plated. Furthermore, since the stirring force of the plating solution is small, there is a possibility that the plating solution cannot be appropriately stirred. Still further, the structure according to each of the combinations above makes the structure for sealing the rotary shaft for rotating the object to be treated complex, and also makes the operations of carrying in and out the object to be treated difficult.

In view of these matters, in the plating machine 1 according to the embodiment described above, in accordance with the rotation of the holder 32 by the wafer rotation drive unit 35, the wafer W is rotated in the circumferential direction in the plating solution of the plating tank 62 at high speed, and thus a high-speed flow of the plating solution is generated. Furthermore, the plurality of treatment units 14, namely, the pre-treatment unit 14a, the plating unit 14b, the water washing unit 14c, the post-treatment unit 14d, the drying unit 14e, and the wafer housing unit 14f are arranged side by side on the same circumference around the center position of the stage 12, and the wafer W is conveyed to the plurality of treatment units 14 by the arc movement of the single conveying arm 31, thereby realizing the processes by the plurality of treatment units 14 as continuous processes.

Furthermore, in the plating machine 1 according to the embodiment described above, after the wafer reversing mechanism 22 reverses the wafer W, the wafer W is held by the holder 32 in this state and conveyed together with the holder 32 to the plurality of treatment units 14. The wafer W is rotated in accordance with the rotation of the holder 32, thereby making it possible to rotate the wafer W at high speed during processes in each of the treatment units 14. In addition, special control corresponding to each process is not required to rotate the wafer W at high speed, and as a result, it is possible to realize the processes by the plurality of treatment units 14 as continuous processes.

### <Others>

In the embodiment described above, on the rotation trajectory of the holder 32, the pre-treatment unit 14a, the plating unit 14b, the water washing unit 14c, the post-treatment unit 14d, the drying unit 14e, and the wafer housing unit 14f are arranged at the predetermined intervals. However, the present invention is not limited thereto, and various types of processing units used for plating can be similarly arranged on the rotation trajectory of the holder 32 at the predetermined intervals.

Furthermore, even wafers other than the wafer W having a single crystal silicon structure or large-diameter wafers that is larger than the minimal wafer of the half-inch size can be adapted and used.

### REFERENCE SIGNS LIST

1 plating machine
2 housing
2a housing upper portion
2b housing lower portion
2c operation panel
2d front chamber
2e docking port
2f air vent
2g fan
2h air filter
2i rectifier
2j scrubber
2k discharge outlet
2m support member
9 PLAD system plating chamber
11 stage
12a insertion recess
13 conveying means
14 treatment unit
14a pre-treatment unit
14b plating unit
14c water washing unit
14d post-treatment unit
14e drying unit
14f wafer housing unit
22 wafer reversing mechanism
23 reversing arm
24 suction pad
25 rotation drive unit
26 vertical movement drive unit
31 conveying arm
32 holder (holding assembly, holding unit)
33 arm rotation drive unit
34 arm vertical movement drive unit
35 wafer rotation drive unit
36 rotary shaft (support assembly)
37 lower part
38 upper part
41 housing recess
42 opening
43 O-ring (sealing means)
44 pressure adjustment hole (pressure adjustment means)
45 covering piece member
46 circumferential surface member
47 engagement recess (locking member)
48 magnetic assembly (integrating means)
49 opening
51 insertion projection
52 electrode unit
53 O-ring (sealing means)
54 support piece member
55 magnet assembly (integrating means)
61 pre-treatment tank
62 plating tank
63 rubber packing (pressure adjustment means)
64 opening (pressure adjustment means)
66 circulation mechanism
66a reservoir tank
66b pump
66c solution drawing pipe
66d nozzle unit
66e overflow task
66f solution returning pipe
67 suction port
71 water washing tank
72 opening
73 drain port
74 post-treatment tank
75 opening
76 drying tank
77 opening
78 chuck mechanism (removal means)
79 engagement piece member (locked unit)
81 partition plate
82 chemical floating region
83 non-chemical floating region
84 opening
W wafer
B surface to he treated
M plating solution

1. A plating machine comprising:
a plurality of treatment units; and
a conveying means that conveys a wafer to the plurality of treatment units,
the conveying means including an arm that is provided, on one end side, with a holding unit that holds the wafer, and an arm rotation drive unit that rotates the arm around another end side of the arm, and
the plurality of treatment units being arranged at predetermined intervals on a rotation trajectory of the holding unit.

2. The plating machine according to claim 1, wherein
the conveying means includes a vertical movement drive unit that moves the holding unit upward and downward.

3. The plating machine according to claim 1, wherein
the holding unit ts rotatably supported around an axis thereof by the arm, and
the conveying means includes a wafer rotation drive unit that rotates the holding unit around the axis thereof.

4. The plating machine according to claim 1, further comprising a stage on which the wafer is delivered, wherein
the stage includes a wafer reversing unit that reverses the wafer delivered on the stage, and conveys the wafer which has been reversed to the holding unit of the conveying means.

5. The plating machine according to claim 4, wherein
the wafer has a surface to be treated on one of upper and lower sides,
the wafer is delivered on the stage with the surface to be treated facing upward,
the wafer reversing unit reverses the wafer delivered on the stage and conveys the wafer to the holding unit with the surface to be treated facing downward, and
the plurality of treatment units performs treatment on the surface to be treated of the wafer which has been facing downward.

6. The plating machine according to claim 1, wherein
the wafer is formed into a disc-shape having as outside diameter of 12.5 mm.
